(19) United States
(12) Patent Application Publication
(10) Pub. No.: US 2020/0168452 A1
(43) Pub. Date: May 28, 2020

(54) METHOD FOR PLANARIZING WAFER SURFACE

(71) Applicant: Shanghai Simgui Technology Co., Ltd., Shanghai (CN)

(72) Inventors: Xing WEI, Shanghai (CN); Nan GAO, Shanghai (CN); Meng CHEN, Shanghai (CN); Xin SU, Shanghai (CN); Hongtao XU, Shanghai (CN)

(73) Assignee: Shanghai Simgui Technology Co., Ltd., Shanghai (CN)

(21) Appl. No.: 16/601,267

(22) Filed: Oct. 14, 2019

(30) Foreign Application Priority Data
Nov. 27, 2018 (CN) 201811423514.2

(51) Int. Cl. H01L 21/02; H01L 21/3213; H01L 21/16; H01L 21/321

(52) U.S. Cl. CPC H01L 21/02019; H01L 21/32137; H01L 21/3212; H01L 21/165; H01L 21/02472; H01L 21/164

(57) ABSTRACT

A method for planarizing a wafer surface comprising: providing a first wafer and a second wafer, oxidizing the first wafer to form an oxide layer on a surface of the first wafer, injecting a foaming ion to form a peeling layer in the first wafer, bonding the first wafer and the second wafer to form a bonded wafer by using the oxide layer as an intermediate layer, raising a temperature to cause the bonded wafer to crack in the peeling layer, a portion of the first wafer remaining on the surface of the oxide layer being a top silicon layer, and the oxide layer being an insulating buried layer, etching a surface of the top silicon layer with a mixed gas of hydrogen and HCl, wherein the mixed gas is injected from a side of the wafer, wherein a flow rate of the mixed gas in an edge region is less than a flow rate of the mixed gas in a central region.

### CROSS-REFERENCE TO RELATED APPLICATION

This application is based upon and claims priority to Chinese Patent Application No. 201811423514.2, filed on Nov. 27, 2018, the entire contents thereof are incorporated herein by reference.

### TECHNICAL FIELD

The present disclosure relates to the technical field of semiconductor material manufacturing, and in particular, relates to a method for planarizing a wafer surface.

### BACKGROUND

SOI is a new generation silicon-base material that is extensively used, which gains more applications in low-voltage and low-power consumption circuits, micro-mechanical sensor, optoelectrical integration and the like fields. With respect to the SOI material, thickness uniformity of top-layer silicon is a critical parameter. This parameter greatly determines performance of a device.

In an SOI process, planarization of the top-layer silicon is generally practiced by a chemical mechanical polishing (CMP) process. With constant reduction of the thickness of the top-layer silicon and stricter requirement on uniformity of the top-layer silicon, the CMP process fails to accommodate relevant process requirements.

### SUMMARY

The present disclosure provides a method for planarizing a wafer surface.

Accordingly, a method for planarizing a wafer surface includes the following steps: providing a wafer, the wafer including an insulating buried layer and a top silicon layer disposed on a surface of the insulating buried layer; and etching a surface of the top silicon layer with a mixed gas of hydrogen and HCl, the mixed gas being injected from a side of the wafer, and a flow rate the mixed gas in an edge region being less than a flow rate of the mixed gas in a central region.

### BRIEF DESCRIPTION OF THE DRAWINGS

FIG. 1 shows a schematic diagram of steps of a method for planarizing a wafer surface, according to an embodiment of the present invention;

FIG. 2A shows a process schematic diagram, according to an embodiment of the present invention;

FIG. 2B shows a process schematic diagram, according to an embodiment of the present invention;

FIG. 2C shows a process schematic diagram, according to an embodiment of the present invention;

FIG. 2D shows a process schematic diagram, according to an embodiment of the present invention;

FIG. 2E shows a process schematic diagram, according to an embodiment of the present invention;

FIG. 3 shows a process schematic diagram, according to an embodiment of the present invention; and

FIG. 4 shows a schematic structural diagram of an etching device, according to an embodiment of the present invention.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the disclosure. Instead, they are merely examples of apparatuses and methods consistent with aspects related to the disclosure as recited in the appended claims.

The terminology used in the present disclosure is for the purpose of describing particular embodiments only and is not intended to limit the present disclosure. As used in the present disclosure and the appended claims, the singular forms “a,” “an,” and “the” are intended to include the plural forms as well, unless the context clearly indicates otherwise. It shall also be understood that the term “and/or” used herein is intended to signify and include any or all possible combinations of one or more of the associated listed items.

It shall be understood that, although the terms “first,” “second,” “third,” etc. may be used herein to describe various information, the information should not be limited by these terms. These terms are only used to distinguish one category of information from another. For example, without departing from the scope of the present disclosure, first information may be termed as second information; and similarly, second information may also be termed as first information. As used herein, the term “if” may be understood to mean “when” or “upon” or “in response to a judgment” depending on the context.

Hereinafter, specific embodiments of a method for planarizing a wafer surface are described in detail with reference to the accompanying drawings.

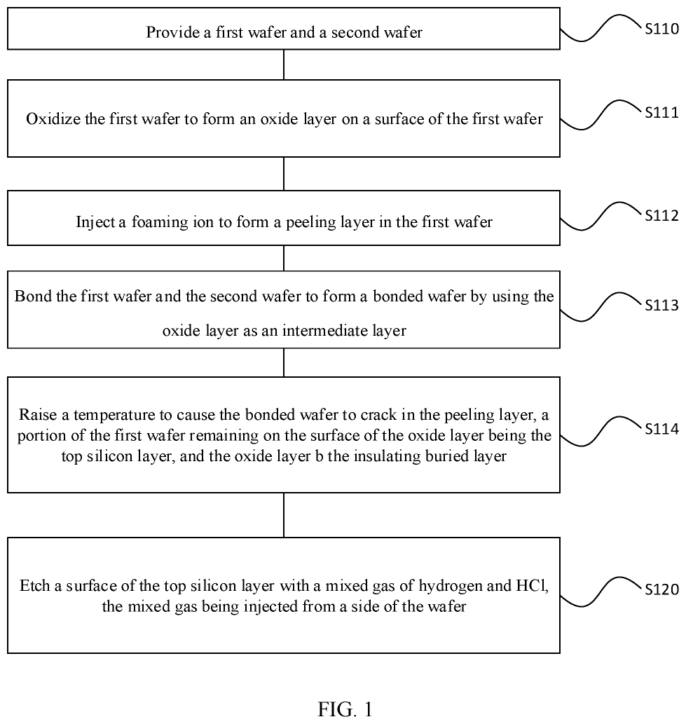

FIG. 1 is a schematic diagram of steps of the method according to a specific embodiment of the present invention. The method includes: step S110: providing a first wafer and a second wafer; step S111: oxidizing the first wafer to form an oxide layer on a surface of the first wafer; step S112: injecting a foaming ion to form a peeling layer in the first wafer; step S113: bonding the first wafer and the second wafer to form a bonded wafer by using the oxide layer as an intermediate layer; step S114: raising a temperature to cause the bonded wafer to crack in the peeling layer, a portion of the first wafer remaining on the surface of the oxide layer being the top silicon layer, and the oxide layer being the insulating buried layer; and step S120: etching a surface of the top silicon layer with a mixed gas of hydrogen and HCl, the mixed gas being injected from a side of the wafer, and a flow rate the mixed gas in an edge region being less than a flow rate of the mixed gas in a central region.

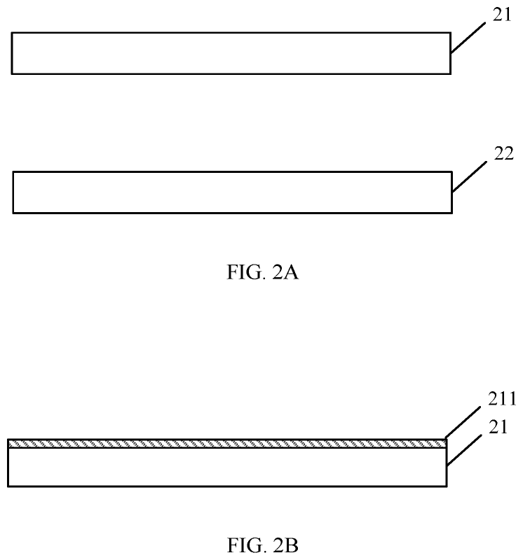

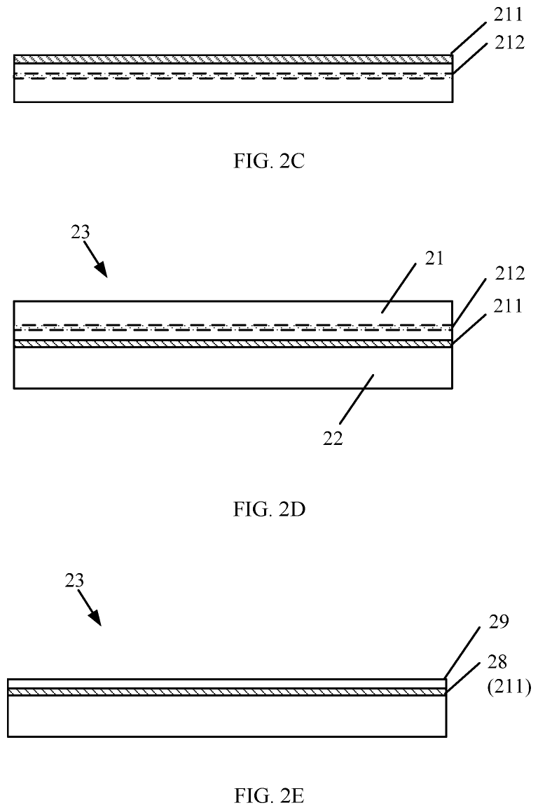

FIG. 2A to FIG. 2E, and FIG. 3 are process schematic diagrams of the above steps.

As illustrated in FIG. 2A, referring to step S110, a first wafer 21 and a second wafer 22 are provided. The first wafer 21 is used for a subsequent peeling process, wherein the surface thereof to be peeled is a monocrystal material. The second wafer 22 is used as a support substrate for bonding, wherein materials thereof may include monocrystal silicon, sapphire, silicon carbide and any other commonly used semiconductor substrate material.

As illustrated in FIG. 2B, referring to step S111, the first wafer 21 is oxidized to form an oxide layer 211 on a surface of the first wafer. The oxidation may be carried out by a dry oxygen or wet oxygen oxidation method, and a material of the formed oxide layer 211 is silica, and the formed oxide layer 211 has a thickness which is less than 500 nm.

As illustrated in FIG. 2C, referring to step S112, a foaming ion is injected to form a peeling layer 212 in the first wafer 21. The foaming ion is selected from the group consisting of hydrogen, helium and a mixture gas of hydrogen and helium, an injection energy is less than 100 keV, and an injection amount is in the range of 1×10¹⁶ cm⁻² to 6×10¹⁶ cm⁻².

As illustrated in FIG. 2D, referring to step S113, the first wafer 21 and the second wafer 22 are bonded to form a bonded wafer 23 by using the oxide layer 211 as an intermediate layer.

As illustrated in FIG. 2E, referring to step S114, a temperature is raised to cause the bonded wafer 23 to crack in the peeling layer 212, wherein a portion of the first wafer remaining on the surface of the oxide layer 211 is the top silicon layer 29, and the oxide layer 211 is the insulating buried layer 28. Cracking of the bonded wafer 23 in the peeling layer 212 is practiced at a temperature in the range of from 300° C. to 600° C. and at a duration of from 10 min to 60 min.

After steps S110 to S114 are performed, the bonded wafer 23 is obtained, which includes the top silicon layer 29 and the insulating buried layer 28. Since the surface of the top silicon layer 29 is a surface obtained by a peeling process, surface roughness is great, and the surface needs to be planarized by a surface treatment process. The above method for obtaining a wafer is the method described in a specific embodiment. In other specific embodiments, more methods may also be employed to obtain a wafer including an insulating buried layer and a top silicon layer on the surface of the insulating buried layer.

As illustrated in FIG. 3, referring to step S120, a surface of the top silicon layer is etched with a mixed gas of hydrogen and HCl, wherein the mixed gas is injected from a side of the wafer 23, and a flow rate the mixed gas in an edge region is less than a flow rate of the mixed gas at a central region. In an embodiment of an etching effect, the top silicon layer 29 is subjected to hydrogen baking before etching to remove a natural oxide layer on the surface thereof. Typically, such surface treatment is carried out at a temperature greater 1100° C. and at a duration over 40 s, to ensure subsequent etching of the silicon by HCl. In this specific embodiment, the step of etching is performed at a temperature greater than 1050° C., and in the step of etching, a volume fraction of HCl in the mixed gas is less than 1%, and the flow rate of the mixed gas is in the range of from 40 L/min to 120 L/min. In an embodiment of an etching effect, an etching removal amount of the top silicon layer 29 is greater than 80 nm. Since the top silicon layer 29 has a small target thickness, which is generally less than 200 nm, even less than 20 nm, the chemical mechanical polishing fails to accommodate the requirement on flatness. With the HCl etching method, surface flatness may be accurately controlled relative to the polishing process, and thus the process requirement is satisfied.

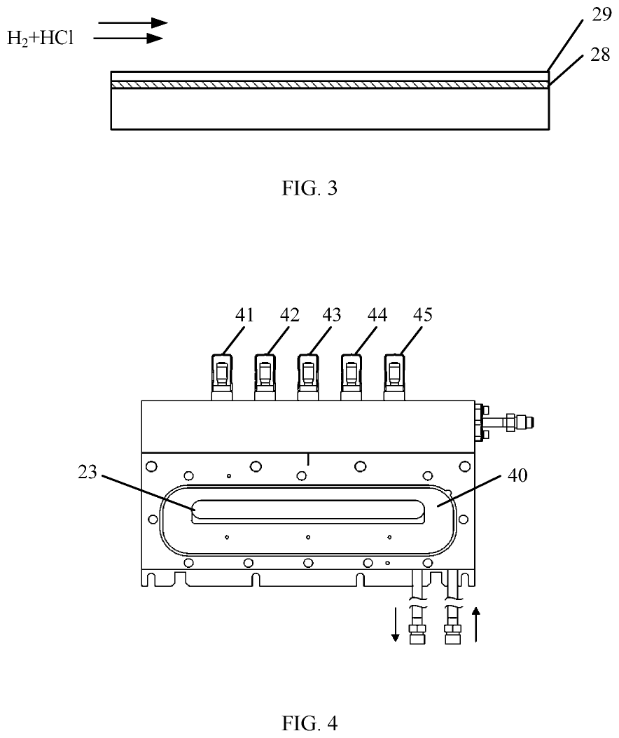

FIG. 4 is a schematic structural diagram of an etching device for practicing the above etching process according to a specific embodiment. The wafer 23 is arranged in a cavity 40, and a plurality of gas nozzles with the flow rate regulatable are employed. In this specific embodiment, the nozzles include nozzles 41 to 45, which respectively correspond to five positions from the center to the edge and regulate the flow rate of the injected gas. The flow rates in the edge and central regions may be regulated based on a device parameter, such that etch uniformity is achieved. In addition, through studies, it is found that where the same gas flow rate is defined at the edge and center regions, the edge region of the wafer has an etching rate that is slightly greater than an etching rate in the central region of the wafer, and thus central symmetric distribution is exhibited. Therefore, in the specific embodiments, the flow rate of the mixed gas in the edge region is defined to be less than that of the mixed gas in the central region to balance the centripetal distribution of the etching rate.

For example, the wafer is formed by the following steps: providing a first wafer and a second wafer; oxidizing the first wafer to form an oxide layer on a surface of the first wafer; injecting a foaming ion to form a peeling layer in the first wafer; bonding the first wafer and the second wafer to form a bonded wafer by using the oxide layer as an intermediate layer; and raising a temperature to cause the bonded wafer to crack in the peeling layer, wherein a portion of the first wafer remaining on the surface of the oxide layer is the top silicon layer, and the oxide layer is the insulating buried layer. The foaming ion is one selected form the group consisting of hydrogen, helium and a mixed gas of hydrogen and helium.

For example, in the step of surface etching, an etching removal amount of the top silicon layer is greater than 80 nm.

For example, a temperature in the step of etching is greater than 1050° C.

For example, in the step of etching, a volume fraction of HCl in the mixed gas is less than 1%.

For example, in the step of etching, the flow rate of the mixed gas is in the range of from 40 L/min to 120 L/min.

Since the top silicon layer has a small target thickness, which is generally less than 200 nm, even less than 20 nm, the chemical mechanical polishing fails to accommodate the requirement on flatness. With the HCl etching method, surface flatness may be accurately controlled relative to the polishing process, and thus the process requirement is satisfied. In addition, through studies, it is found that where the same flow rate is defined at the edge and center regions, the edge region of the wafer has an etching rate that is slightly greater than an etching rate in the central region of the wafer, and thus centripetal distribution is exhibited. Therefore, in the specific embodiments, the flow rate of the mixed gas in the edge region is defined to be less than that of the mixed gas in the central region to balance the centripetal distribution of the etching rate.

Described above are embodiments of the present invention. It should be noted that persons of ordinary skill in the art may derive other improvements or polishments without departing from the principles of the present invention. Such improvements and polishments shall be deemed as falling within the protection scope of the present invention.

What is claimed is:

1. A method for planarizing a wafer surface, comprising:
providing a first wafer and a second wafer;
oxidizing the first wafer to form an oxide layer on a surface of the first wafer;
injecting a foaming ion to form a peeling layer in the first wafer;
bonding the first wafer and the second wafer to form a bonded wafer by using the oxide layer as an intermediate layer;
raising a temperature to cause the bonded wafer to crack in the peeling layer, a portion of the first wafer remaining on the surface of the oxide layer being a top silicon layer, and the oxide layer being an insulating buried layer; and
etching a surface of the top silicon layer with a mixed gas of hydrogen and HCl, wherein the mixed gas is injected from a side of the wafer, wherein a flow rate of the mixed gas in an edge region is less than a flow rate of the mixed gas in a central region.

2. The method according to claim 1, wherein the foaming ion is either hydrogen, helium, or a mixed gas of hydrogen and helium.

3. The method according to claim 1, wherein etching a surface of the top silicon layer with a mixed gas of hydrogen and HCl comprises an etching removal amount of the top silicon layer of more than 80 nm.

4. The method according to claim 1, wherein raising a temperature to cause the bonded wafer to crack in the peeling layer comprises raising the temperature greater than 1050° C.

5. The method according to claim 1, wherein etching a surface of the top silicon layer with a mixed gas of hydrogen and HCl comprises a volume fraction of HCl in the mixed gas of less than 1%.

6. The method according to claim 1, wherein etching a surface of the top silicon layer with a mixed gas of hydrogen and HCl comprises the flow rate of the mixed gas in the range of 40 L/min to 120 L/min.

7. A method for planarizing a wafer surface, comprising:
providing a wafer, the wafer comprising an insulating buried layer and a top silicon layer disposed on a surface of the insulating buried layer; and
etching a surface of the top silicon layer with a mixed gas of hydrogen and HCl, the mixed gas being injected from a side of the wafer, and a flow rate the mixed gas in an edge region being less than a flow rate of the mixed gas in a central region.

8. The method according to claim 7, wherein the wafer is formed by the following steps:
providing a first wafer and a second wafer;
oxidizing the first wafer to form an oxide layer on a surface of the first wafer;
injecting a foaming ion to form a peeling layer in the first wafer;
bonding the first wafer and the second wafer to form a bonded wafer by using the oxide layer as an intermediate layer; and
raising a temperature to cause the bonded wafer to crack in the peeling layer, a portion of the first wafer remaining on the surface of the oxide layer being the top silicon layer, and the oxide layer being the insulating buried layer.

8. The method according to claim 7, wherein the foaming ion is either hydrogen, helium, or a mixed gas of hydrogen and helium.

9. The method according to claim 8, wherein etching a surface of the top silicon layer with a mixed gas of hydrogen and HCl comprises an etching removal amount of the top silicon layer is more than 80 nm.

10. The method according to claim 7, wherein raising a temperature to cause the bonded wafer to crack in the peeling layer comprises raising the temperature greater than 1050° C.

11. The method according to claim 7, wherein etching a surface of the top silicon layer with a mixed gas of hydrogen and HCl comprises a volume fraction of HCl in the mixed gas is less than 1%.

12. The method according to claim 7, wherein etching a surface of the top silicon layer with a mixed gas of hydrogen and HCl comprises the flow rate of the mixed gas is in the range of 40 L/min to 120 L/min.
